(19) United States
(12) Patent Application Publication
(10) Pub. No.: US 2025/0386607 A1
(43) Pub. Date: Dec. 18, 2025

(54) Colloidal Quantum Dots on a Matrix of Silicon Photomultiplier Microcells

(71) Applicant: SEMICONDUCTOR COMPONENTS INDUSTRIES, LLC, Scottsdale, AZ (US)

(72) Inventors: Brian Patrick MCGARVEY, Templemartin (IE); Michael Gerard KEYES, Dromcollogher (IE); Vladimir KOROBOV, San Mateo, CA (US)

(73) Assignee: SEMICONDUCTOR COMPONENTS INDUSTRIES, LLC, Scottsdale, AZ (US)

(21) Appl. No.: 18/746,250

(22) Filed: Jun. 18, 2024

(51) Int. Cl. H01L 27/146; B82Y 20/00

(52) U.S. Cl. CPC H10F 39/805; B82Y 20/00; H10F 39/184; H10F 39/8067; H10F 39/811

(57) ABSTRACT

The technology employs colloidal quantum dots (CQDs), in which a CQD layer is arranged over an array of SiPM microcells of an image sensor for an imaging module. Separate biases are applied to the CQD layer and to the microcell array. A method includes biasing the CQD layer of an imaging module at a first voltage, and biasing an array of photomultiplier microcells at a second voltage. Upon receiving a photon, the CQD layer generates a charge in response. The charge moves from the CQD layer into the array, where at least one photomultiplier microcell amplifies the charge. A signal from the imaging module is then output according to the amplified charge. This approach can significantly increase photon detection efficiency of an imaging element, which can be employed in a wide variety of applications such as lidar, medical imaging, and night vision or for other low-light imaging situations.

### BACKGROUND

Imaging devices are used in many different types of applications. They receive photons from the external environment and can generate imagery or other representations of the environment based on the received photons. Each photon results in a single charge generation event (e.g., an electron or a hole). Converting this charge generation event into a detectable current can be challenging, especially in situations where there may be relatively few received photons, such as at night or in medical imaging applications. A silicon photomultiplier (SiPM) approach can be employed, but this may also be inadequate in many instances.

### BRIEF SUMMARY

The technology relates to enhanced imaging, in particular to an approach that employs colloidal quantum dots (CQDs). In this approach, a CQD layer is arranged over an array of SiPM microcells of an image sensor for an imaging module. Separate biases are applied to the CQD layer and to the microcell array. This arrangement may significantly increase photon detection efficiency of an imaging element, which can be employed in applications such as light detection and ranging (lidar), medical imaging, and night vision or for other low-light imaging situations (e.g., to detect heat signatures of objects in the surrounding environment).

According to one aspect of the technology, imaging circuitry comprises a colloidal quantum dot (CQD) layer and a conductor layer disposed on the CQD layer. The conductor layer is transparent to one or more wavelengths of light to be received by the imaging circuitry. The conductor layer is configured to bias a voltage of the CQD layer. The circuitry also comprises an array of photomultiplier microcells, the array having a set of first electrodes adjacent to the CQD layer opposite the conductor layer, and having a second electrode remote from the CQD layer. The set of first electrodes and the second electrode are configured to bias a voltage of each of the photomultiplier microcells in the array. The circuitry also comprises a bulk layer disposed adjacent to the array and remote from the CQD layer. The photomultiplier microcells may be silicon microcells.

The imaging circuitry may further comprise a cover layer, in which the conductor layer is arranged between the cover layer and the CQD layer. For example, the cover layer may comprise glass or polycarbonate. The conductor layer may comprise indium tin oxide (ITO). Each portion of the CQD layer may include at least 100 quantum dots associated with a corresponding photomultiplier microcell of the array. Each photomultiplier microcell of the array may have an area on the order of 10-200 μm².

The bias for the photomultiplier microcells in the array may be selected to cause each microcell to operate in Geiger mode. The bias for the CQD layer may be lower than the bias for the photomultiplier microcells in the array.

Quantum dots of the CQD layer may comprise lead sulfide (PbS) or other materials. Quantum dots of the CQD layer may have a selected quantum efficiency in a short-wave infrared (SWIR) spectrum. In certain scenarios, the imaging circuitry may operate in a backside illumination mode or in a in a frontside illumination mode.

According to another aspect of the technology, an imaging module comprises imaging circuitry and an illumination module. The imaging circuitry includes a colloidal quantum dot (CQD) layer and a conductor layer disposed on the CQD layer. The conductor layer is transparent to one or more selected wavelengths of light to be received by the imaging circuitry. The conductor layer is configured to bias a voltage of the CQD layer. The imaging circuitry also includes an array of photomultiplier microcells, in which the array has a set of first electrodes adjacent to the CQD layer opposite the conductor layer, and a second electrode remote from the CQD layer. The set of first electrodes and the second electrode are configured to bias a voltage of each of the photomultiplier microcells in the array. The imaging circuitry also includes a bulk layer disposed adjacent to the array and remote from the CQD layer. The illumination module is configured to illuminate an external environment of the imaging module at the one or more selected wavelengths of light. The one or more selected wavelengths of light may be in a short-wave infrared (SWIR) spectrum.

According to a further aspect of the technology, an imaging method comprises: biasing a colloidal quantum dot (CQD) layer of an imaging module at a first voltage; biasing an array of photomultiplier microcells of the image module at a second voltage; receiving at least one photon at the CQD layer; generating, by the CQD layer, a charge in response to the received photon; the charge moving from the CQD layer into the array; at least one of the photomultiplier microcells amplifying the charge; and outputting a signal from the imaging module according to the amplified charge.

The array of photomultiplier microcells may be configured to reflect un-detected photons back to the CQD layer. The biasing of the array of photomultiplier microcells may cause each microcell to operate in Geiger mode. The biasing for the CQD layer may be lower than the biasing for the array of photomultiplier microcells. Quantum dots of the CQD layer may have a selected quantum efficiency in a short-wave infrared (SWIR) spectrum.

### BRIEF DESCRIPTION OF THE DRAWINGS

FIG. 1 illustrates an exemplary imaging system in accordance with aspects of the technology.

FIG. 2 illustrates an example image capture scene in accordance with aspects of the technology.

FIG. 3 is a block diagram of a pixel array and readout assembly for an image sensor in accordance with aspects of the technology.

FIG. 4 illustrates a side view of an exemplary imaging element in accordance with aspects of the technology.

FIG. 5 illustrates a perspective view of the exemplary imaging element of FIG. 4.

FIG. 6 illustrates an exemplary circuit arrangement for an imaging element in accordance with aspects of the technology.

FIG. 7 illustrates an example method in accordance with aspects of the technology.

### DETAILED DESCRIPTION

As noted above, the technology provides an enhanced imaging approach, which employs a CQD layer along with a photomultiplier arrangement (such as SiPM) in order to generate a suitable detectable current from received photons. Notably, biasing for the CQD layer is independent from biasing across the photomultiplier arrangement. As discussed further below, there may be hundreds or thousands of CQDs (or more) associated with each cell in the photomultiplier arrangement. The following provides exemplary discussions of an imaging system and (image) pixel readout, which may be employed with aspects of the technology. An example scenario is also provided. These examples are non-limiting.

For instance, one approach may involve short-wave infrared (SWIR)-based imaging. The SWIR spectrum is in the range of about 1000 to 3000 nm. This range can be important, both for eye safety and also for imaging in harsh weather conditions such as rain, snow, or fog. By way of example, an SWIR emitter can employ a laser having a wavelength on the order of 1550 nm, 2000 nm, or elsewhere within the SWIR spectrum. Employing a CQD layer in conjunction with SWIR can noticeably improve the imaging process for lidar and other applications, such as by expanding detectable wavelengths.

### Example Imaging System

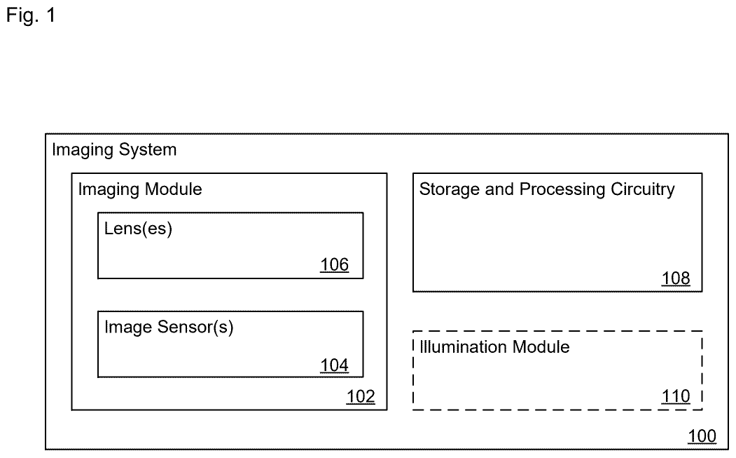

FIG. 1 is a block diagram of an exemplary imaging system 100, such as an electronic device that employs sensor circuitry (also referred to as a sensor module) to capture imagery. Imaging system 100 may comprise or be part of a still or video camera, a webcam, a mobile phone, a laptop or tablet computer, a video surveillance system, a vehicle imaging system, a video game system with imaging capabilities, an augmented reality (AR) and/or virtual reality (VR) system, an unmanned aerial vehicle system (such as a drone), a commercial or industrial system, etc. Camera (or imaging) module 102 is configured to convert incoming/received light into digital image data. The imaging module 102 includes one or more image sensors (or sensor modules) 104. While the imaging module 102 may be configured for optical imaging, in other aspects the system may be configured for other imaging approaches, such as lidar imaging (e.g., in the near-infrared spectrum), medical imaging (e.g., positron emission tomography (PET) scanning), etc.

During an image capture process, light from a scene is focused onto the image sensor(s) 104 by one or more corresponding lenses 106. Image sensors 104 may include circuitry for generating analog pixel image signals and circuitry for converting those image signals into corresponding digital image data. The digital image data may be provided to storage and processing circuitry 108.

Storage and processing circuitry 108 may include, e.g., one or more integrated circuits (ICs), such as image processing circuits, microprocessors, storage devices such as random-access memory (RAM) and/or non-volatile memory (NVM), etc. This circuitry may be implemented using components that are separate from imaging module 102 or that may form part of imaging module 102. When storage and processing circuitry 108 is implemented on different ICs than those implementing imaging module 102, the ICs with circuitry 108 may be stacked or otherwise packaged with the ICs for imaging module 102.

Image data that has been captured by imaging module 102 may be processed and stored using processing circuitry 108 (e.g., using an image processing engine of processing circuitry 108, using an imaging mode selection engine on processing circuitry 108, etc.). Processed image data may be provided to external equipment such as a computer, a vehicle control system, a medical imaging system, an external display, or other devices using a wired or wireless communications path coupled to processing circuitry 108 (not shown).

In the example of FIG. 1 as shown in the dashed box, imaging module 102 may include an illumination module 110, which can be configured to emit light for illuminating objects in an image scene. Image sensor(s) 104 may be configured to gather reflected versions of the emitted light and to generate image information for the scene. By way of example only, such image information may include depth or distance information for one or more objects, a depth or distance map of the image scene, an image of the image scene, etc.

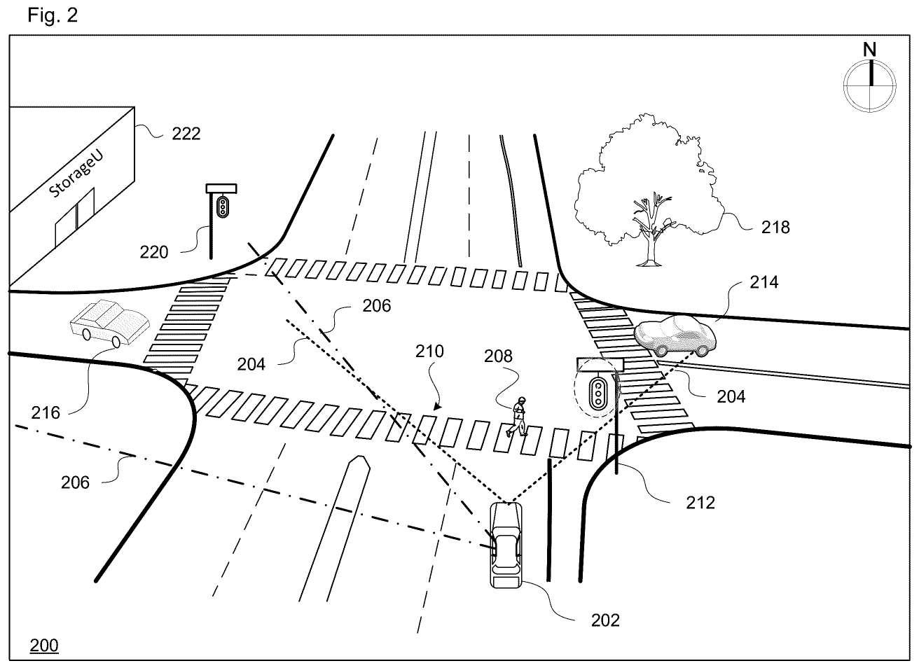

The illumination module 110, such as a light emitter controlled by driver circuitry (not shown), may emit light having any suitable characteristic(s). This can include any suitable waveform, peak amplitude or power, periodicity or frequency, pulses of light, light with a modulated amplitude and a modulation frequency, etc. The emitted light may be in the infrared (IR) such as SWIR and/or optical bands, and may be generated by an LED or a laser configured to emit one or more light pulses, such as in a light pulse train. The emitted light may reach one or more objects in an image scene and reflect off of such objects, returning to the camera module 102 as reflected light. Objects may include any suitable objects, whether fixed or mobile. By way of example only, in a driving scene for a vehicle operating in an autonomous (or manual) driving mode (see FIG. 2), objects may include signage, street light, driving or bike lanes, curbs or sidewalks, other road users (e.g., other vehicles, bicyclists or pedestrians), trees or shrubbery, etc.

Reflected light may be received at the image sensor 104 (e.g., at one or more active image pixels, at one or more photosensitive elements in the active image pixels, etc.). Driver circuitry and/or control circuitry may control the pixels to generate one or more image frames based on the reflected light, such as by providing control signals coupled to transistors or other actuated elements (e.g., switching elements) in the pixels. In particular, based on the received control signals from the driver circuitry and/or control circuitry, the pixels may generate different portions of charge in response to reflected light (e.g., during an integration or exposure time period), may perform one or more readout operations on the generated portions of charge (e.g., during a readout time period), or may perform other operations during other time periods.

Processing circuitry in imaging module 102 or processing circuitry in the imaging system 100) may control illumination module 110 and know the characteristics of the emitted light signal. The processing circuitry may then control the image sensor(s) 104 to generate image signals for one or multiple image frames, which are indicative of the characteristics of the reflected light signal. The system may process (e.g., compare and correlate) the generated image signals for these image frames to the reflected light and to emitted light to determine a phase difference and/or time of flight information.

### Example Imaging Scenario

FIG. 2 illustrates an exemplary image sensing scenario 200, where the image sensor(s) 104 are part of a perception system of a vehicle 202. The perception system may be configured to obtain imagery (e.g., lidar imagery) from one or more fields of view of the vehicle, such as a front-facing field of view indicated by dotted lines 204, or a side facing field of view as indicated by dash-dot lines 206. Note that in this example, the fields of view 204 and 206 overlap. As shown, there are a number of objects in the nearby external environment of the vehicle 202. Those objects include pedestrian 208, crosswalk 210, a traffic light 212 on the southeast corner of the intersection, vehicle 214 heading westbound, vehicle 216 heading eastbound, tree 218, a traffic light 220 on the northwest corner, and a store 222.

The image sensors arranged along the vehicle to provide the different fields of view may each have an illumination module. The light emitted from the illumination module(s) may be modulated or otherwise controlled so that reflected light received from the external environment corresponds to objects at specific distances or within specific ranges. By way of example, this may be done with the front-facing image sensor to obtain imagery including the pedestrian 208, who may be 10-15 meters from the vehicle, as well as the vehicle 214, which may be 25-40 meters from the vehicle. Similarly, this may be done with the side-facing image sensor to obtain imagery of the vehicle 216, which may be 50-60 meters away, the traffic light 220, which may be 60-75 meters away, and the store 222, which may be 80-100 meters from the vehicle.

Additional exemplary image sensing scenarios include where the image sensor(s) 104 are part of an imaging/detection system for machine vision imaging, inspection, surveillance/security, medical imaging, or other applications.

### Example Pixel Array and Readout Assembly

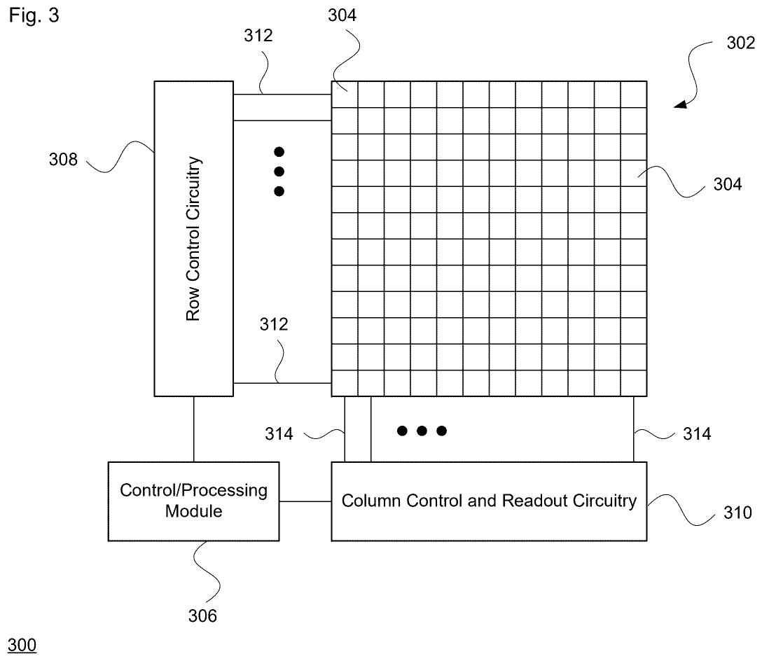

FIG. 3 is a diagram of an illustrative configuration for an image pixel array and readout assembly 300 for the image sensor 104 of FIG. 1. As shown in FIG. 3, the assembly 300 includes a pixel array 302 containing sensor pixels 304 arranged in rows and columns, along with control and processing circuitry in module 306. The array 302 may contain, for example, tens, hundreds, or thousands of rows and columns of sensor pixels 304. Module 306 may be coupled to row control circuitry 308 (sometimes referred to as row driver circuitry or pixel driver circuitry) and column control and readout circuitry 310 (sometimes referred to as column readout circuitry or column control circuitry, readout circuitry, or column decoder circuitry). Control module 306 may receive (row) addresses from row control circuitry 308 and supply corresponding (row) control signals such as reset, anti-blooming, row select (or pixel select), modulation, storage, charge transfer, readout, sample-and-hold, and/or store control signals to pixels 304 over (row) control paths 312.

One or more lines such as column lines 314 may be coupled to each column of pixels 304 in array 302. Column lines 314 may be used for reading out image signals from pixels 304 and for supplying bias signals (e.g., bias currents or bias voltages) to pixels 304. The column control and readout circuitry 310 may receive image signals (e.g., analog pixel values generated by pixels 304) over lines 314. This circuitry 310 may include memory circuitry for storing calibration signals (e.g., reset level signals, reference level signals) and/or image signals (e.g., image level signals) read out from the array 302, amplifier circuitry or a multiplier circuit, analog to digital conversion (ADC) circuitry, bias circuitry, latch circuitry for selectively enabling or disabling the portions (columns) of the circuitry 310, or other circuitry that is coupled to one or more pixels in array 302 for operating pixels 304 and for reading out image signals from pixels 304. ADC circuitry in the circuitry 310 may convert analog pixel values received from array 302 into corresponding digital pixel values (sometimes referred to as digital image data or digital pixel data). The circuitry 310 may supply digital pixel data to control/processing module 306 for pixels 304 (e.g., in one or more pixel columns).

The pixel array 302 may also be provided with a filter array having multiple (color) filter elements each corresponding to a respective pixel, which allows a single image sensor to sample light of different colors or sets of wavelengths. In general, filter elements of any desired color and/or wavelength (e.g., optical or infrared wavelengths) and in any desired pattern may be formed over any desired number of image pixels 304. By way of example, for time-of-flight sensing using an illumination source (e.g., in illumination module 110 in FIG. 1), the pixel array 302 may be provided with a correspond filter array that passes light having colors and/or frequencies emitted from the illumination source.

The image sensors 104 of imaging module 102 (FIG. 1) may include one or more arrays 302 of image pixels 304. The image pixels 304 may be formed in a semiconductor substrate using complementary metal-oxide-semiconductor (CMOS) technology, charge-coupled device (CCD) technology, or any other suitable photosensitive device technology. Image pixels 304 may be frontside illumination (FSI) image pixels or backside illumination (BSI) image pixels. Moreover, the array 302 may include pixels 304 of different types such as active pixels, optically shielded pixels, reference pixels, etc. If desired, the image sensor(s) may include an integrated circuit package or other structure in which multiple integrated circuit substrate layers (e.g., from multiple wafers) or chips are vertically stacked or otherwise arranged with respect to each other.

According to aspects of the technology discussed in detail below, the pixels may comprise an array of SiPM microcells or another type of photomultiplier, having a CQD layer arranged thereon.

### Example Imaging Circuitry

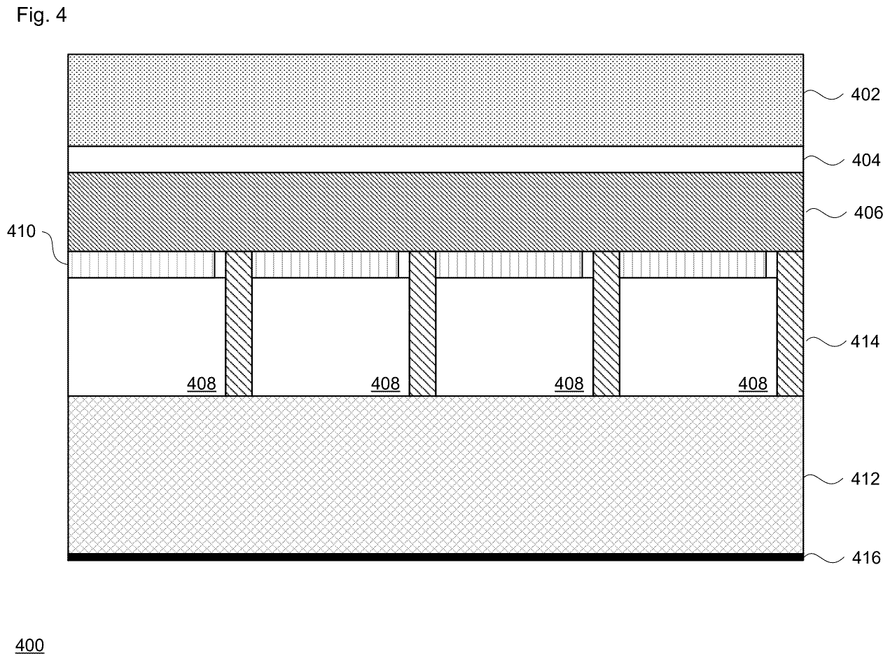

FIG. 4 illustrates an example CQD-microcell configuration 400. As shown, this configuration includes a cover layer 402 arranged over a transparent conductor 404. By way of example, the cover layer 402 may comprise, e.g., glass or clear polycarbonate, and the transparent conductor 404 may be, e.g., an optically transparent conductive film layers such as indium tin oxide (ITO).

Below the transparent conductor 404 is a CQD layer 406. The CQD layer 406 is arranged on an array of photomultiplier microcells 408, such as SiPM microcells. As shown here, there is a first (or top) electrode 410 for each microcell 408. A (silicon) bulk layer 412 may act as a second (or bottom) electrode for each microcell 408. Buffers 414 are shown separating adjacent microcells. The buffers 414 may also be silicon. The bulk layer 412 may be disposed on a carrier wafer 416. The bulk layer 412 may be used in an FSI configuration, whereas the carrier wafer 416 may be used in a BSI configuration. In one configuration, the layer with the ITO conductor 404 can be patterned in a matrix at the same pitch as the microcell layer.

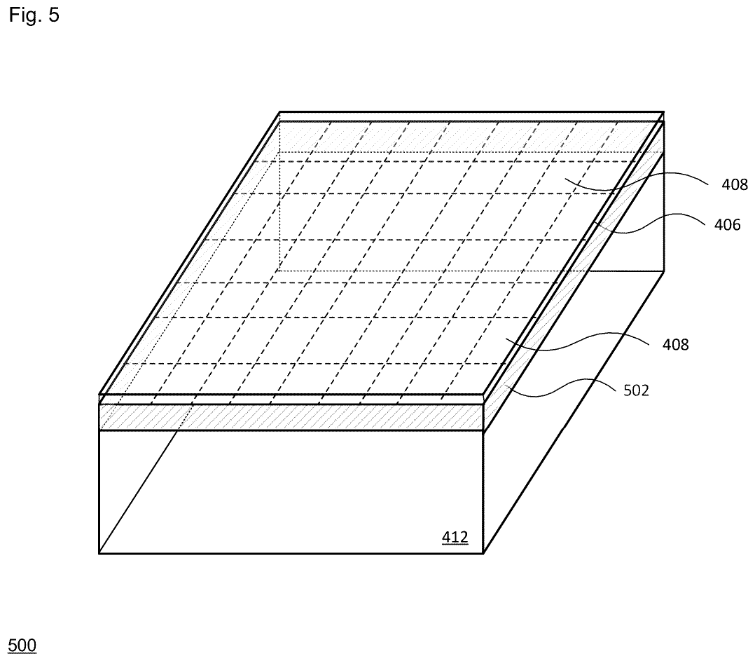

FIG. 5 illustrates a perspective view 500 of a portion of the CQD-microcell configuration. In this figure, the cover layer 402 and the transparent conductor 404 are omitted. Here, CQD layer 406 is shown disposed over an array 502 of the microcells 408, illustrated as an array having N×M microcells 408. By way of example, N and M are integers ranging from 1-1,000 (or more), for instance depending on the number of pixels or desired resolution of the imaging module. Furthermore, there may be hundreds, thousands or more CQDs associated with each microcell 408. By way of example only, the area of a single CQD may be on the order of 10-150 nm² (or more or less), while the area of an SiPM microcell may be on the order of 10-200 μm² (or more or less).

When considered as a circuit, each SiPM microcell of the array would have an avalanche photodiode (APD) and a quenching resistor arranged (Rq) in series. All of the microcells in a given array may be operatively coupled in parallel. Therefore, the array effectively has two nodes: an anode and a cathode. There may be a common anode for all of the microcells, e.g., the silicon bulk layer 412. In this case, the cathodes would be the electrodes 410. The SiPMs are electrically biased between the anode and the cathode, in which the voltage applied to each APD is above its breakdown voltage. In other words, each APD would operate in Geiger mode, which occurs when the APD is reverse biased above its breakdown voltage, so that electrons and holes are able to multiply faster than they may be extracted from the APD.

Overvoltage is the difference between the biasing and breakdown voltages, and can be the primary adjustable parameter controlling microcell operation. For instance, when a microcell absorbs photons, the resulting charge carriers (either holes or electrons depending on device structure) may trigger an avalanche in the gain region of the device. The gain corresponds to the amount of (charge) carriers produced by the avalanche process. The quenching resistor, Rq, is used to restore Geiger mode operation to the APD. The gain depends on the overvoltage and junction capacitance of the device. Note that the SiPM microcells do not store charge like charge-coupled devices (CCDs) would. Rather, they act as photodetectors capable of producing a time-varying output signal measurable in real time. The output comprises a discrete distribution of amplitudes.

Quantum dots of the CQD layer are nanocrystal particles that act as semiconductors. These particles have a small size in the nanometer range as noted above, and have optoelectronic properties with quantum mechanical effects. These properties may vary as a function of both size and shape of the specific particles employed. For instance, particles having a relatively larger size may absorb longer wavelengths than particles having a relatively smaller size. This can result in specific colors being detected, but that can depend on the particular composition of the quantum dot.

CQDs are formed via a colloidal method, which may be a hot injection approach, room temperature approach, or other technique. For instance, insoluble precipitate particles may be formed under a selected temperature and pressure. By way of example only, the CQDs may be formed, e.g., of a binary compound such as lead sulfide (PbS), although other binary compounds may be indium arsenide or indium phosphide, cadmium telluride, cadmium selenide, cadmium sulfide, lead selenide, etc. Ternary compounds, for instance cadmium selenide sulfide, may alternatively be used. A bandgap corresponding to a desired wavelength may be obtained by selecting an appropriate CQD composition.

The CQD layer is arranged in relation to the microcell array, e.g., as shown in FIGS. 4-5. By way of example, this can be done by sputtering or another deposition/fabrication technique. In one scenario, the cover layer (e.g., glass) with a thin, optically clear conducting film (e.g., ITO) is applied over the CQD layer. The conducting film may be disposed on the side of the cover layer that will contact the CQD layer. The film may be formed lithographically in a selected pattern. Once the QCD-microcell layout is completed, the wafer can be diced or otherwise separated into multiple image sensors for one or more imaging modules.

As noted above, CQDs can be configured to respond to a selected wavelength of light. For instance, CQDs may have relatively high quantum efficiency of approximately 15% in the SWIR spectrum, e.g., on the order of 1500 nm, although CQDs can be chosen to respond to other wavelengths. Impingement of a photon on a given CQD results in a single charge generation event (electron or hole), and the generated charge drifts or otherwise moves to one of the microcells in the array. The field in the micro-cell will sweep the charge into the avalanche region, resulting in a current avalanche, thereby amplifying the original single charge.

With reference to FIG. 4, the conductor 404 is configured to apply a bias setting for the CQD layer 406 relative to the first electrode 410. A separate microcell bias would be applied between electrodes 410 and 412. The microcell top electrode 410 may be metal, which enables reflection of un-detected photons back into the CQD layer 406 in an FSI process as noted above, or implanted silicon or another suitable conductor. Alternatively, the top electrode 410 may be a shared electrode in contact with the CQD layer. This would be according to a BSI process in which the resistor would be on the carrier wafer.

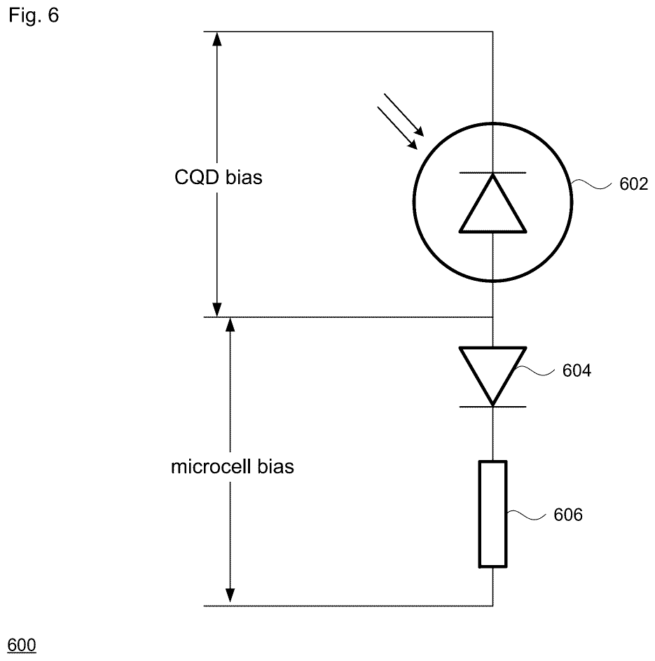

An example showing the biases is illustrated in the exemplary circuit arrangement 600 of FIG. 6. Here, CQD detector 602 can correspond to a number of quantum dots in the CQD layer 406 associated with a given microcell 408. As shown, when considered as a circuit, the microcell has an APD 604 and an Rq 606 in series. The CQD bias and the microcell bias are shown across the CQD detector 602 and the series APD-Rq elements, respectively. In one scenario, the CQD bias may be on the order of 0.4-0.8 volts, or in the range of 0.25-1.5 volts. In contrast, the microcell bias may be much higher, e.g., on the order of 20-40 volts, or more or less.

During operation, in one example the system may keep a CQD bias of between 0.6-0.8 volts, while an SiPM microcell array is kept in reverse bias. In one alternative, the voltage for the SiPM array may be switched to be at breakdown.

Note that CQDs have a relatively long reset time relative to microcell reset time. For instance, the CQD reset time may be on the order of 75-125 μs, whereas an SiMP microcell array may have a reset time on the order of 10-50 ns.

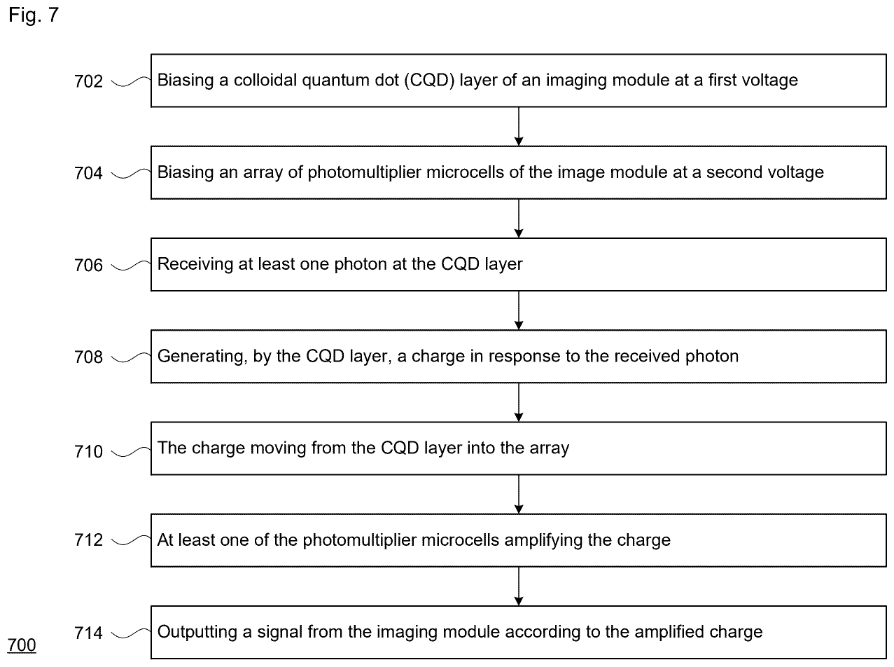

FIG. 7 illustrates a method 700, which includes at block 702 biasing a colloidal quantum dot (CQD) layer of an imaging module at a first voltage, and at block 704 biasing an array of photomultiplier microcells of the image module at a second voltage. These biasing operations may occur in parallel or in any order. At block 706 the method includes receiving at least one photon at the CQD layer. At block 708 the method includes generating, by the CQD layer, a charge in response to the received photon. At block 710, the charge moves from the CQD layer into the array. At block 712 the method includes at least one of the photomultiplier microcells amplifying the charge. And at block 714 the method includes outputting a signal from the imaging module according to the amplified charge.

Thus, as described herein the CQD-photomultiplier microcell approach can provide significant improvements for SWIR imaging techniques, such as lidar applications, night vision or other low-light imaging situations, etc. The quantum dots may be selected so that the CQD layer helps enhance light amplification for specific wavelengths (or bands of wavelengths) depending on the application.

Although the technology herein has been described with reference to particular embodiments/configurations, it is to be understood that these are merely illustrative of the principles and applications of the present technology. It is therefore to be understood that numerous modifications may be made to the illustrative embodiments and that other arrangements may be devised without departing from the spirit and scope of the present technology as defined by the appended claims. By way of example only, components that are illustrated as being arranged in series may have a complementary configuration in parallel; similarly, components that are illustrated as being arranged in parallel may have a complementary configuration in series.

1. Imaging circuitry, comprising:
a colloidal quantum dot (CQD) layer;
a conductor layer disposed on the CQD layer, the conductor layer being transparent to one or more wavelengths of light to be received by the imaging circuitry, the conductor layer configured to bias a voltage of the CQD layer;
an array of photomultiplier microcells, the array having a set of first electrodes adjacent to the CQD layer opposite the conductor layer, and having a second electrode remote from the CQD layer, wherein the set of first electrodes and the second electrode are configured to bias a voltage of each of the photomultiplier microcells in the array; and
a bulk layer disposed adjacent to the array and remote from the CQD layer.

2. The imaging circuitry of claim 1, wherein the photomultiplier microcells are silicon microcells.

3. The imaging circuitry of claim 1, further comprising a cover layer, wherein conductor layer is arranged between the cover layer and the CQD layer.

4. The imaging circuitry of claim 3, wherein the cover layer comprises glass or polycarbonate.

5. The imaging circuitry of claim 1, wherein the conductor layer comprises indium tin oxide (ITO).

6. The imaging circuitry of claim 1, wherein each portion of the CQD layer includes at least 100 quantum dots associated with a corresponding photomultiplier microcell of the array.

7. The imaging circuitry of claim 1, wherein each photomultiplier microcell of the array has an area on the order of 10-200 μm².

8. The imaging circuitry of claim 1, wherein the bias for the photomultiplier microcells in the array is selected to cause each microcell to operate in Geiger mode.

9. The imaging circuitry of claim 1, wherein the bias for the CQD layer is lower than the bias for the photomultiplier microcells in the array.

10. The imaging circuitry of claim 1, wherein quantum dots of the CQD layer comprise lead sulfide (PbS).

11. The imaging circuitry of claim 1, wherein quantum dots of the CQD layer have a selected quantum efficiency in a short-wave infrared (SWIR) spectrum.

12. The imaging circuitry of claim 1, wherein the imaging circuitry operates in a backside illumination mode.

13. The imaging circuitry of claim 1, wherein the imaging circuitry operates in a frontside illumination mode.

14. An imaging module, comprising:
imaging circuitry including:
a colloidal quantum dot (CQD) layer;
a conductor layer disposed on the CQD layer, the conductor layer being transparent to one or more selected wavelengths of light to be received by the imaging circuitry, the conductor layer configured to bias a voltage of the CQD layer;
an array of photomultiplier microcells, the array having a set of first electrodes adjacent to the CQD layer opposite the conductor layer, and having a second electrode remote from the CQD layer, wherein the set of first electrodes and the second electrode are configured to bias a voltage of each of the photomultiplier microcells in the array; and
a bulk layer disposed adjacent to the array and remote from the CQD layer; and
an illumination module configured to illuminate an external environment of the imaging module at the one or more selected wavelengths of light.

15. The imaging module of claim 14, wherein the one or more selected wavelengths of light are in a short-wave infrared (SWIR) spectrum.

16. An imaging method, comprising:
biasing a colloidal quantum dot (CQD) layer of an imaging module at a first voltage;
biasing an array of photomultiplier microcells of the image module at a second voltage;
receiving at least one photon at the CQD layer;
generating, by the CQD layer, a charge in response to the received photon;
the charge moving from the CQD layer into the array;
at least one of the photomultiplier microcells amplifying the charge; and
outputting a signal from the imaging module according to the amplified charge.

17. The imaging method of claim 16, wherein the array of photomultiplier microcells is configured to reflect un-detected photons back to the CQD layer.

18. The imaging method of claim 16, wherein the biasing of the array of photomultiplier microcells causes each microcell to operate in Geiger mode.

19. The imaging method of claim 16, wherein the biasing for the CQD layer is lower than the biasing for the array of photomultiplier microcells.

20. The imaging method of claim 16, wherein quantum dots of the CQD layer have a selected quantum efficiency in a short-wave infrared (SWIR) spectrum.
